(19) United States
(12) Patent Application Publication
(10) Pub. No.: US 2007/0259488 A1
(43) Pub. Date: Nov. 8, 2007

(54) Single layer construction for ultra small devices

(75) Inventors: Jonathan Gorrell, Gainesville, FL (US); Mark Davidson, Florahome, FL (US); Jean Tokarz, Hawthorne, FL (US); Andres Trucco, Gainesville, FL (US)

Correspondence Address: DAVIDSON BERQUIST JACKSON & GOWDEY LLP, 4300 WILSON BLVD., 7TH FLOOR, ARLINGTON, VA, 22203, US

(73) Assignee: Virgin Islands Microsystems, Inc., St. Thomas, VI (US)

(21) Appl. No.: 11/418,080

(22) Filed: May 5, 2006

(51) Int. Cl. H01L 21/338

(52) U.S. Cl. 438/185

(57) ABSTRACT

An array of ultra-small structures of between ones of nanometers to hundreds of micrometers in size that can be energized to produce at least two different frequencies of out put energy or data, with the ultra small structures being formed on a single conductive layer on a substrate. The array can include one row of different ultra small structures, multiple rows of ultra small structures, with each row containing identical structures, or multiple rows of a variety of structures that can produce all spectrums of energy or combinations thereof, including visible light.

### CROSS-REFERENCE TO CO-PENDING APPLICATIONS

The present invention is related to the following co-pending U.S. patent applications: (1) U.S. patent application Ser. No. 11/238,991 [atty. docket 2549-0003], filed Sep. 30, 2005, entitled “Ultra-Small Resonating Charged Particle Beam Modulator”; (2) U.S. patent application Ser. No. 10/917,511 [atty. docket 2549-0002], filed on Aug. 13, 2004, entitled “Patterning Thin Metal Film by Dry Reactive Ion Etching”; (3) U.S. application Ser. No. 11/203,407 [atty. docket 2549-0040], filed on Aug. 15, 2005, entitled “Method Of Patterning Ultra-Small Structures”; (4) U.S. application Ser. No. 11/243,476 [Atty. Docket 2549-0058], filed on Oct. 5, 2005, entitled “Structures And Methods For Coupling Energy From An Electromagnetic Wave”; (5) U.S. application Ser. No. 11/243,477 [Atty. Docket 2549-0059], filed on Oct. 5, 2005, entitled “Electron beam induced resonance,”, (6) U.S. application Ser. No. 11/325,432 [Atty. Docket 2549-0021], entitled “Resonant Structure-Based Display,” filed on Jan. 5, 2006; (7) U.S. application Ser. No. 11/325,571 [Atty. Docket 2549-0063], entitled “Switching Micro-Resonant Structures By Modulating A Beam Of Charged Particles,” filed on Jan. 5, 2006; (8) U.S. application Ser. No. 11/325,534 [Atty. Docket 2549-0081], entitled “Switching Micro-Resonant Structures Using At Least One Director,” filed on Jan. 5, 2006; (9) U.S. application Ser. No. 11/350,812 [Atty. Docket 2549-0055], entitled “Conductive Polymers for the Electroplating”, filed on Feb. 10, 2006; (10) U.S. application Ser. No. 11/302,471 [Atty. Docket 2549-0056], entitled “Coupled Nano-Resonating Energy Emitting Structures,” filed on Dec. 14, 2005; (11) U.S. application Ser. No. 11/325,448 [Atty. Docket 2549-0060], entitled “Selectable Frequency Light Emitter”, filed on Jan. 5, 2006; and (12) U.S. application Ser. No. ______ [Atty. Docket 2549-0086], entitled “Method For Coupling Out Of A Magnetic Device”, filed on even date herewith, which are all commonly owned with the present application, the entire contents of each of which are incorporated herein by reference.

### COPYRIGHT NOTICE

A portion of the disclosure of this patent document contains material which is subject to copyright or mask work protection. The copyright or mask work owner has no objection to the facsimile reproduction by anyone of the patent document or the patent disclosure, as it appears in the Patent and Trademark Office patent file or records, but otherwise reserves all copyright or mask work rights whatsoever.

### FIELD OF THE DISCLOSURE

This disclosure relates to producing and using ultra-small metal structures formed by using a combination of various coating, etching and electroplating processing techniques and accomplishing these processing techniques using a single conductive layer, and to the formation of ultra small structures on a substrate that can resonate at two or more different frequencies on the single layer. The frequencies can vary between micro-wave and ultra-violet electromagnetic radiation, and preferably will produce visible light in two or more different frequencies or colors that can then be used for a variety of purposes including data exchange and the production of useful light.

### INTRODUCTION AND SUMMARY

In its broadest form, the process disclosed herein produces ultra-small structures with a range of sizes described as micro- or nano-sized. The processing begins with a non-conductive substrates (e.g., glass, oxidized silicon, plastics and many others) or a semi-conductive substrate (e.g., doped silicon, compound semiconductor materials (GaAs, InP, GaN, . . . )), or a conductive substrate. The optimal next step can be the coating or formation of a thin layer of nickel followed by the coating or formation of a thin layer of silver on the nickel layer. Then a single layer of a conductive material, such as silver, gold, nickel, aluminum, or other conductive material is then applied, deposited, coated or otherwise provided on the thin silver layer, and the conductive layer is then etched or patterned into the desired ultra-small shaped devices, or the substrate, on which the thin nickel and silver layers had been coated, is provided with a mask layer which is patterned and then a conductive material is deposited, plated or otherwise applied. Thereafter, the mask layer can be removed, although in some instances that may not be necessary.

Electroplating is well known and is fully described in the above referenced '407 application. For present purposes, electroplating is the preferred process to employ in the construction of ultra-small resonant structures.

An etching could also be used, for example by use of chemical etching or Reactive Ion Etching (RIE) techniques, as are described in the above mentioned '511 application, to develop a final pattern in the conductive layer.

Where a photoresist material is first applied to the substrate, and patterned, then a coating or plating process as is explained in the above mentioned '407 application could be used. In that case, the patterned base structure will be positioned in an electroplating bath and a desired metal will be deposited into the holes formed in the mask or protective layer exposed by one or more of the prior etching processing steps. Thereafter, the mask or photoresist layer can be removed leaving formed metal structures on the substrate exhibiting an ultra small size, or alternatively the PR layer will be removed leaving the formed metal structures lying directly on the substrate.

Ultra-small structures encompass a range of structure sizes sometimes described as micro- or nano-sized. Objects with dimensions measured in ones, tens or hundreds of microns are described as micro-sized. Objects with dimensions measured in ones, tens or hundreds of nanometers or less are commonly designated nano-sized. Ultra-small hereinafter refers to structures and features ranging in size from hundreds of microns in size to ones of nanometers in size.

### GLOSSARY

As used throughout this document:

The phrase “ultra-small resonant structure” shall mean any structure of any material, type or microscopic size that by its characteristics causes electrons to resonate at a frequency in excess of the microwave frequency.

The term “ultra-small” within the phrase “ultra-small resonant structure” shall mean microscopic structural dimensions and shall include so-called “micro” structures, “nano” structures, or any other very small structures that will produce resonance at frequencies in excess of microwave frequencies.

### BRIEF DESCRIPTION OF FIGURES

The invention is better understood by reading the following detailed description with reference to the accompanying drawings in which:

FIG. 1 is a schematic diagram of a first example and embodiment of the present invention;

FIG. 2 is a graph showing intensity versus post or finger length for the series of rows of ultra small structures;

FIG. 3 is a perspective view of another embodiment of the present invention;

FIG. 4 is a view of another embodiment of the present invention;

FIG. 5 is a graph showing an example of intensity and wavelength versus finger or post length for a series of ultra small structures;

FIG. 6 an example of another embodiment of the present invention; and

FIG. 7 is another embodiment of the present invention.

### DESCRIPTION OF THE PRESENTLY PREFERRED EXEMPLARY EMBODIMENTS OF THE INVENTION

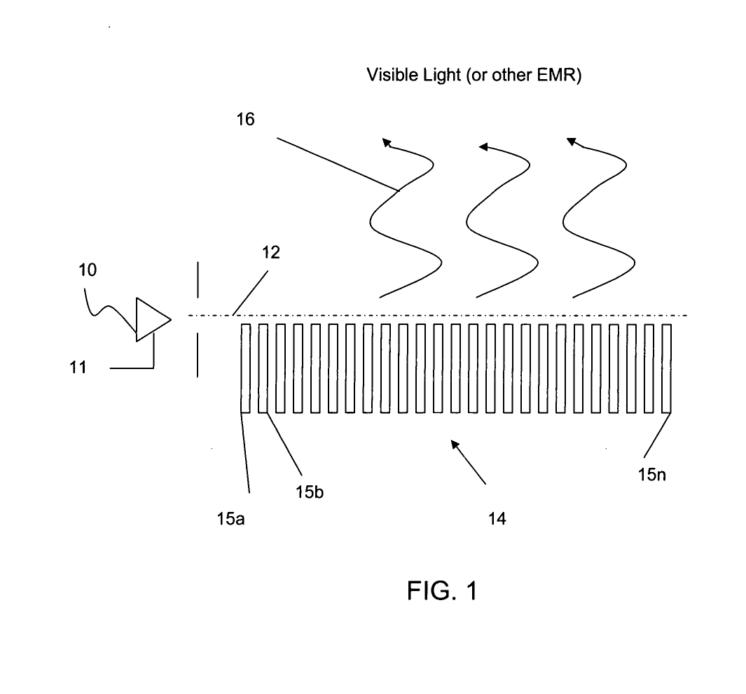

As shown in FIG. 1, a single layer of metal, such as silver or other thin metal, is produced with the desired pattern or otherwise processed to create a number of individual resonant structures to form a resonant element 14. Although sometimes referred to herein as a “layer” of metal, the metal need not be a contiguous layer, but can be a series of structures or, for example, posts or fingers 15 that are individually present on a substrate 13 (such as a semiconductor substrate or a circuit board) and area designated as 15A, 15b, ______ 15n.

When forming the posts 15, while the posts 15 can be isolated from each other, there is no need to remove the metal between posts or fingers 15 all the way down to the substrate level, nor does the plating have to place the metal posts directly on the substrate, but rather they can be formed on the thin silver layer or the silver/nickel layer referenced above which has been formed on top of the substrate, for example. That is, the posts or fingers 15 may be etched or plated in a manner so a layer of conductor remains beneath, between and connecting the posts. Alternatively, the posts or fingers can be conductively isolated from each other by removing the entire metal layer between the posts, or by not even using a conductive layer under the posts or fingers. In one embodiment, the metal can be silver, although all other conductors and conductive materials, and even dielectrics, are envisioned as well.

A charged particle beam, such as an electron beam 12 produced by an electron microscope, cathode, or any other electron source 10, that is controlled by applying a signal on a data input line 11. The source 10 can be any desired source of charged particles such as an electron gun, a cathode, an electron source from a scanning electron microscope, etc. The passing of such an electron beam 12 closely by a series of appropriately-sized resonant structures 15, causes the electrons in the structures to resonate and produce visible light or other EMR 16, including, for example, infrared light, visible light or ultraviolet light or any other electromagnetic radiation at a wide range of frequencies, and often at a frequency higher than that of microwaves. In FIG. 1, resonance occurs within the metal posts 15 and in the spaces between the metal posts 15 on a substrate 13 and with the passing electron beam. The metal posts 15 include individual post members 15a, 15b, . . . 15n. The number of post members 15a . . . 15n can be as few as one and as many as the available real estate permits. We note that theoretically the present resonance effect can occur in as few as only a single post, but from our practical laboratory experience, we have not measured radiation from either a one post or two post structures. That is, more than two posts have been used to create measurable radiation using current instrumentation.

The spaces between the post members 15a, 15b, . . . 15n (FIG. 1) create individual cavities. The post members and/or cavities resonate when the electron beam 12 passes by them. By choosing different geometries of the posts and resonant cavities, and the energy (velocity) of the electron beam, one can produce visible light (or non-visible EMR) 16 of a variety of different frequencies including, for example, a variety of different colors in the case of visible emissions, from just a single patterned metal layer.

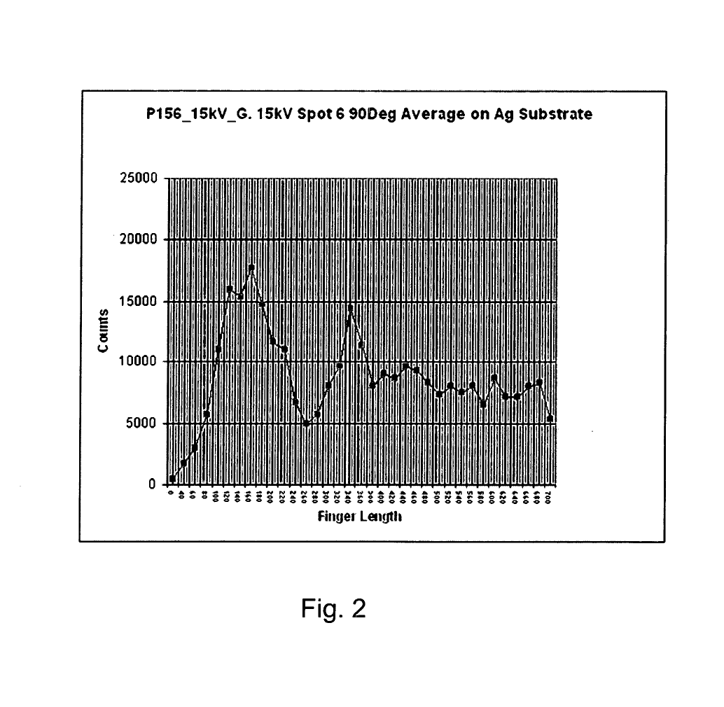

That resonance is occurring can be seen in FIG. 2. There, the average results of a set of experiments in which the radiation intensity from an example of the present invention was plotted (in the y-axis, labeled “counts” of photons, and measured by a photo multiplier tube as detected current pulses) versus the length of the fingers or posts 15 that are resonating (in the x-axis, labeled as “finger length”). The intensity versus finger or post length average plot shows two peaks (and in some experimental results with more intense outputs, a third peak was perhaps, though not conclusively, present) of radiation intensity at particular finger lengths. For additional discussion, reference can be made to U.S. application Ser. No. 11/243,477, previously referenced above, and which is, in its entirety, incorporated herein by reference. We conclude that certain finger lengths produce more intensity at certain multiple lengths due to the resonance effect occurring within the posts 15.

Exemplary resonant structures are illustrated in several copending applications, including U.S. application Ser. No. 11/325,432, noted above and is, in its entirety, incorporated herein by reference. As shown in FIG. 1, the resonant element 14 is comprised a series of posts or fingers 15 which are separated by a spacing 18 measured as the beginning of one finger 15a to the beginning of an adjacent finger 15b. Each post 15 also has a thickness that takes up a portion of the spacing between posts 15. The posts 15 also have a length 125 and a height (not shown). As illustrated, the posts of FIG. 1 are perpendicular to the beam 12. As demonstrated in the above co-pending application, the resonant structures can have a variety of shapes not limited to the posts 15 shown in FIG. 2 herein, and all such shape variations are included herein.

Resonant structures, here posts 15, are fabricated from resonating material (e.g., from a conductor such as metal (e.g., silver, gold, aluminum and platinum or from an alloy) or from any other material that resonates in the presence of a charged particle beam). Other exemplary resonating materials include carbon nanotubes and high temperature superconductors.

When creating the resonating elements 14, and the resonating structures 15, according to the present invention, the various resonant structures can be constructed in multiple layers of resonating materials but are preferably constructed in a single layer of resonating material as described hereinafter.

In one single layer embodiment, all the resonant structures 15 of a resonant element 14 are formed by being etched, electroplated or otherwise formed and shaped in the same processing step.

At least in the case of silver, etching does not need to remove the material between segments or posts all the way down to the substrate level, nor does the plating have to place the posts directly on the substrate. Silver posts can be on a silver layer on top of the substrate. In fact, we discovered that, due to various coupling effects, better results are obtained when the silver posts are set on a silver layer, which itself is on the substrate.

As noted previously, the shape of the posts 15 may also be shapes other than rectangles, such as simple shapes (e.g., circles, ovals, arcs and squares), complex shapes (e.g., such as semi-circles, angled fingers, serpentine structures and embedded structures (i.e., structures with a smaller geometry within a larger geometry, thereby creating more complex resonances)) and those including waveguides or complex cavities. The finger structures, regardless of any particular shape, will be collectively referred to herein as “segments.”

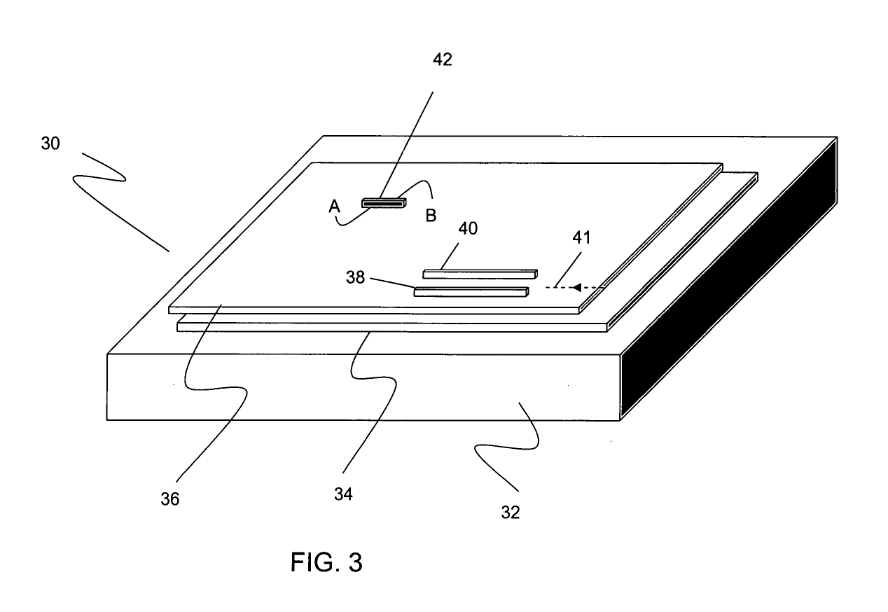

Turning now to specific exemplary embodiments, for example a chip 30 as shown in FIG. 3, can be comprised of a substrate 32 that has been provided with a thin layer of nickel 34, or other adhesive layer or material, at, for example, a thickness of about 10 nm, and a layer of silver 36 having, for example, a thickness of about 100 nm. As shown, the chip 30 includes two rows 38 and 40 of posts or periodic structures, preferably adjacent one another, each being comprised of a plurality of ultra-small structures or segments, which collectively comprise an array of ultra small structures, a resonating element, which will resonate at two different frequencies. For example, one row could be arranged to resonate at one frequency while the other could be arranged to resonate at another and different frequency. As explained above, and in the above copending applications, the ultra-small structures in rows 38 and 40 can be formed by etching or plating techniques, and can have a wide variety of shapes and sizes, with a variety of spacing there between and a variety of heights. Through a selection of these parameters as obtained by such processing techniques, and with reference to what is desired to be accomplished, a chip 30 can be provided, for example, with a row of a plurality of ultra-small structures that will produce, for example, green light and another row, for example, that could produce and output, such as, for example, red light. It must be understood and appreciated that the light or other EMR being emitted by rows 38 and 40, when energized or excited by a beam of charged particles as is shown at 41, is desirably achieved by having the emission of energy be at any two different frequencies, whether in the visible light spectrum, the microwave spectrum, the infra-red spectrum or some other energy spectrum. The invention centers around having ultra small structures formed in one layer of a conductive material, and either isolated or connected as discussed herein, so that they will resonate at two or more different frequencies.

The present invention is not limited to having only one array comprised of two rows of ultra-small structures. For example, the invention contemplates having a single row 42 comprised of a plurality of the ultra-small resonant structure, but with the row 42 having two different sections, A and B formed of different ultra-small resonant structures, with the A section resonating at one frequency while the B section resonates at a different frequency. In this instance, the two sections, A and B, will emit energy at different frequencies even though they are contained in one row of structures. Also, the present invention could, for example, also encompass a device, such as a chip, where its surface is completely filled with or occupied by various arrays of ultra-small structures each of which could be identical to one another, where each was different, or where there were patterns of similar and dissimilar arrays each of which could be emitting or receiving energy or light at a variety of frequencies according to the pattern designed into the arrays of ultra small structures. The processing techniques discussed and disclosed herein, and in the above referenced applications incorporated herein by reference, permit production of any order, design, type, shape, arrangement, size and placement of arrays, elements, posts, segments and/or ultra-small structures, or any grouping thereof, as a designer may wish, in order to achieve an input, output onto or from the surface of the chip to provide light, data transfer or other information or data into or out of the chip or both, or between different parts of a chip or adjacent chips.

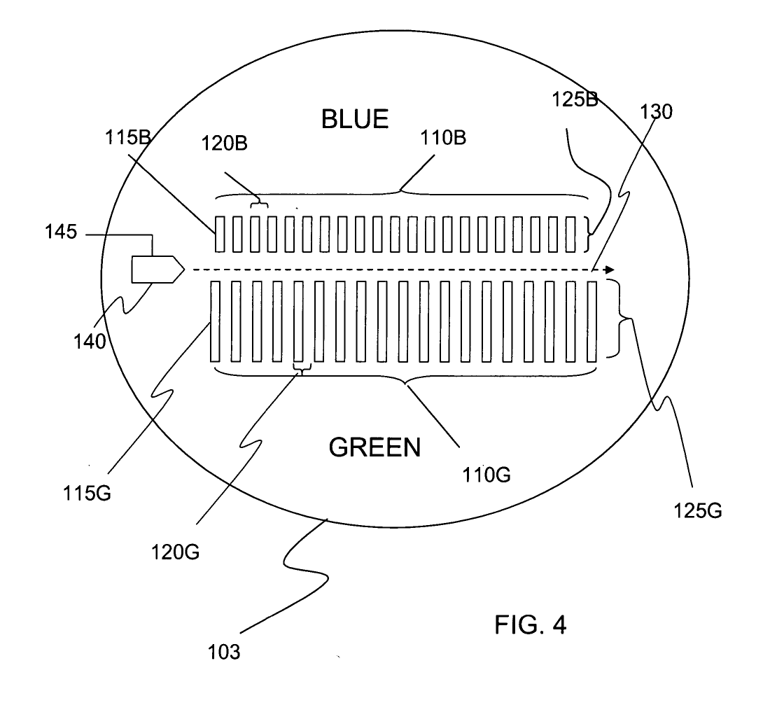

Another exemplary array of resonant elements is shown in FIG. 4, where one wavelength element 110B, comprised of posts or fingers 115B, with a spacing between posts or fingers shown at 120B, lengths at 125B and heights (not shown), for producing electromagnetic radiation with a first frequency, for example a blue color, has been constructed on a substrate 103 so as to be on one side of a beam 130 of charged particles (e.g., electrons, or positively of negatively charged ions) and a second wavelength element 110G, comprised of posts or fingers 115G, with a spacing between posts or fingers shown at 120G, lengths at 125G and heights (not shown), for producing electromagnetic radiation with a second frequency, for example a green color, has been constructed on a substrate 103 so as to be the opposite side of the beam 130. It should be understood that other forms of these wavelength elements could be formed, including using a wavelength element that would produce a red color could be used in place of either the blue or green elements, or that combination elements comprised of ultra small structures that would produce a variety of colors could also be used. However, the spacing and lengths of the fingers 115G and 115B of the resonant structures 110G and 110B, respectively, are for illustrative purposes only and are not intended to represent any actual relationship between the period or spacing 120 of the fingers, the lengths of the fingers 115 and the frequency of the emitted electromagnetic radiation. However, the dimensions of exemplary resonant structures are provided in Table 1 below including for red light producing structures.

TABLE 1

| Wave- | Period | Segment | | | # of fingers |
|---|---|---|---|---|---|
| length | 120 | thickness | Height | Length 125 | in a row |
| Red | 220 nm | 110 nm | 250-400 nm | 100-140 nm | 200-300 |
| Green | 171 nm | 85 nm | 250-400 nm | 180 nm | 200-300 |
| Blue | 158 nm | 78 nm | 250-400 nm | 60-120 nm | 200-300 |

As dimensions (e.g., height and/or length) change, the intensity of the radiation may change as well. Moreover, depending on the dimensions, harmonics (e.g., second and third harmonics) may occur. For post height, length, and width, intensity appears oscillatory in that finding the optimal peak of each mode created the highest output. When operating in the velocity dependent mode (where the finger period depicts the dominant output radiation) the alignment of the geometric modes of the fingers are used to increase the output intensity. However it is seen that there are also radiation components due to geometric mode excitation during this time, but they do not appear to dominate the output. Optimal overall output comes when there is constructive modal alignment in as many axes as possible.

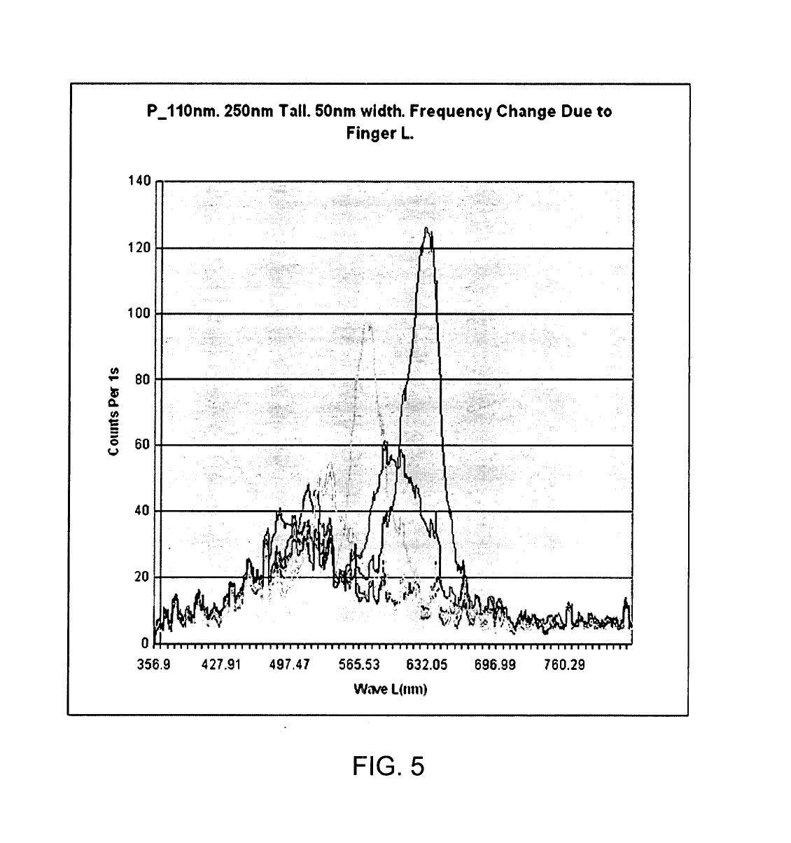

We have also detected that, unlike the general theory on Smith-Purcell radiation, which states that frequency is only dependant on period and electron beam characteristics (such as beam intensity), the frequency of our detected beam changes with the finger length. Thus, as shown in FIG. 5, the frequency of the electromagnetic wave produced by the system on a row of 220 nm fingers (posts) has a recorded intensity and wavelength greater than at the lesser shown finger lengths. With Smith-Purcell, the frequency is related to the period of the grating (recalling that Smith-Purcell is produced by a diffraction grating) and beam intensity according to:

$$λ = \frac{L}{\vert n \vert} \cdot ( \frac{1}{β} - sin θ )$$

where λ is the frequency of the resonance, L is the period of the grating, n is a constant, β is related to the speed of the electron beam, and θ is the angle of diffraction of the electron.

Each of the dimensions mentioned above can be any value in the nanostructure range, i.e., 1 nm to 1 μm. Within such parameters, a series of posts can be constructed that output substantial EMR in the infrared, visible and ultraviolet portions of the spectrum and which can be optimized based on alterations of the geometry, electron velocity and density, and metal/layer type. It should also be possible to generate EMR of longer wavelengths as well. Unlike a Smith-Purcell device, the resultant radiation from such a structure is intense enough to be visible to the human eye with only 30 nanoamperes of current.

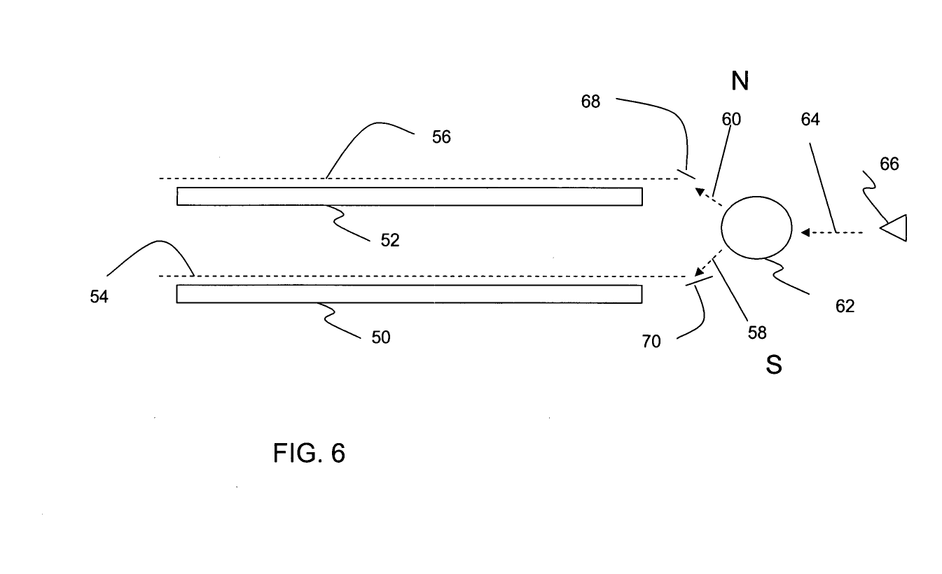

FIG. 6 shows another exemplary embodiment of the present invention where two rows comprised of a plurality of resonating structures, 50 and 52, can be arranged in two parallel rows, or alternatively the rows can be arranged at any desired angle. A charged particle beam 54 and 56 are directed past the rows 50 and 52, respectively by the operation of a magnetic element/cell 62 which can be in one of two states, referred to here as “N” and “S”. Such a magnetic element/cell 62 is also referred to herein as a bi-state device or cell or element. A beam 64 of charged particles (emitted by an emitter 66—a source of charged particles) is deflected by the magnetic element 62, depending upon and according to the state of the magnetic element. When the magnetic element 62 is in its so-called “N” state, the particle beam 64 will be deflected in the N direction, along path 60 to a reflector 68 which then deflects the beam along a path 56 parallel to row 52. When the magnetic element 62 is in its so-called “S” state, the particle beam 64 will be deflected in the S direction along a path 58 toward a reflector 70 that then deflects the beam among a path 54 parallel to row 50. It should be understood that rows 50 and 52 could be angled to be parallel with beam paths 58 and 60, respectively, or at any other angle with deflectors 70 and 68 being appropriately angled to direct the beam along the row of resonating elements.

For the sake of this description, the drawings show the particle beam traveling in both the N and the S directions. Those of skill in the art will immediately understand that the charged particle beam will only travel in one of those directions at any one time.

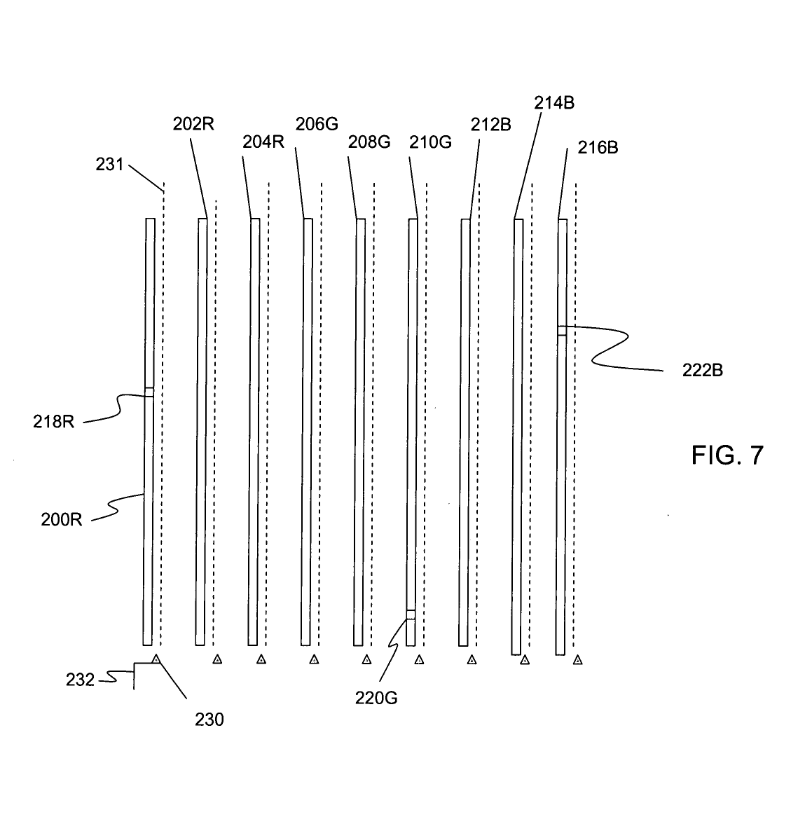

FIG. 7 shows another embodiment where a plurality of rows of wavelength elements 200R-216B have been formed as a composite array on a substrate 106 so that all three visible light spectrums can be produced by the array (i.e., red, green and blue). The spacings between and the lengths of the fingers or posts being used, 218R, 220G, and 222B of the resonant structures 200R-204R, 206G-210G, and 212B-216B, respectively, are for illustrative purposes only, and are not intended to represent any actual relationship between the period or spacings between the fingers or posts, the length of the fingers or posts and the frequency of the emitted electromagnetic radiation. Reference can be made to Table 1 above for specifics concerning these parameters.

As shown in FIG. 7, each row of resonant structures 200R-216B can include its own source of charged particles 232, or as discussed above concerning FIG. 6 a magnetic element or other forms of beam deflectors, as referenced in the above related applications, which have been incorporated herein, can be used to direct beams of charged particles past these rows of resonating structures. It should also be understood that rows 200R, 202R and 204R, for example, could be formed so that each produced exactly the same color and shade of red, or each could be formed to produce a different shade of that color, for example light red, medium red and/or dark red. This concept of having color shading applies equally as well to the green and blue portions of the array.

Each row 200R-216B will produce a uniform light output, yet the combination of the plurality of rows, and the plurality of fingers or posts in each row, permits each row to be controlled so that the whole array can be tuned or constructed, by a choice of the parameters mentioned herein and in the above noted co-pending applications, to produce the light or other EMR output desired.

It should also be understood that the present invention is not limited to having three rows of each of three colors, but rather to the concept of having at least a sufficient number of ultra small structures that will produce two different frequencies on the same surface at the same time. Thus, the chip or what ever other substrate is to be used, could have, and the invention contemplates, all possible combinations of ultra small structures whether in individual rows, adjacent rows or non-adjacent rows, as well as all combinations of colors and shadings thereof as are possible to produce, as well as all possible combinations of the production of frequencies in other or mixed spectrums. Further, the surface can have a limited number of ultra small structures that will accomplish that objective including, as well, as many rows and as many ultra small structure as the surface can hold, including individual rows each of which are comprised of a plurality of different ultra small structures.

While the invention has been described in connection with what is presently considered to be the most practical and preferred embodiment, it is to be understood that the invention is not to be limited to the disclosed embodiment, but on the contrary, is intended to cover various modifications and equivalent arrangements included within the spirit and scope of the appended claims.

What is claimed is:

1. An array of ultra-small structures on a surface, comprising:
a substrate;
at least first and second ultra-small resonant structures formed on the substrate with the first and second ultra-small resonant structures each producing a different frequency output;
a conductive layer positioned beneath each of the ultra-small resonant structures; and
a source of a beam of charged particles directed toward the at least first and second ultra-small resonant structures so that each ultra-small resonant structure resonates at its desired frequency.

2. The array as in claim 1 wherein said ultra-small resonant structures are comprised of a material selected from the group consisting silver (Ag), nickel (Ni), copper (Cu), aluminum (Al), gold (Au) and platinum (Pt).

3. The array as in claim 1 further including a plurality of each of the first and second ultra-small resonant structures, with the plurality of the first and second ultra-small resonant structures being space apart from each other.

4. The array as in claim 1 wherein said first and second ultra-small resonant structures are formed by an electroplating process.

5. The array as in claim 1 wherein said first and second ultra-small resonant structures are formed by coating and etching techniques.

6. The array as in claim 1 wherein a conductive material extends between each of the ultra-small resonant structures

7. The array as in claim 3 wherein the plurality of first and second ultra-small resonant structures are formed in respective rows.

8. The array as in claim 7 wherein the rows are straight.

9. The array as in claim 1 further including a plurality of rows comprised of a plurality of spaced apart ultra-small resonant structures, with the ultra-small resonant structures being formed on a single conductive layer, and with each row within the plurality of rows producing a different frequency output when energized by the beam of charged particles.

10. The array as in claim 9 wherein the substrate comprises a chip.

11. The array as in claim 9 wherein further including a deflector to control the beam of charged particles relative to the plurality of rows.
